(19) United States
(12) Patent Application Publication
(10) Pub. No.: US 2024/0006231 A1
(43) Pub. Date: Jan. 4, 2024

(54) METHOD FOR MANUFACTURING A PAVED STRUCTURE

(71) Applicant: COMMISSARIAT À L'ENERGIE ATOMIQUE ET AUX ENERGIES ALTERNATIVES, Paris (FR)

(72) Inventors: Pierre MONTMEAT, Grenoble (FR); Frank FOURNEL, Grenoble (FR)

(73) Assignee: COMMISSARIAT À L'ENERGIE ATOMIQUE ET AUX ENERGIES ALTERNATIVES, Paris (FR)

(21) Appl. No.: 18/217,074

(22) Filed: Jun. 30, 2023

(30) Foreign Application Priority Data
Jun. 30, 2022 (FR) 22/06643

(51) Int. Cl. H01L 21/762; H01L 21/683; E01F 11/00; H01L 21/324

(52) U.S. Cl. CPC H01L 21/76254; H01L 21/6836; E01F 11/00; H01L 21/3247; H01L 2221/68336; H01L 2221/68363

(57) ABSTRACT

A method for manufacturing a paved structure comprising:
a) providing a vignetted structure comprising a rigid frame, vignettes bonded in a spaced manner on the rigid frame provided with an UV-sensitive adhesive film,
b) bonding the vignettes to a support substrate through a mineral-based paste so as to form a stack,
c) applying a pressure on the stack so that the mineral-based paste fills the space between the vignettes,
d) insolating the UV-sensitive adhesive film,
e) separating the rigid frame and the vignettes integral with the support substrate, and
f) applying a thermal treatment so as to transform the mineral-based paste into a cohesive mineral material to obtain the paved structure.

The present invention relates to the field of the transfer of a vignette made of semiconductor material onto a support substrate. In particular, the present invention concerns a method for manufacturing a paved structure suitable for subsequent functionalization operations comprising in particular a film transfer by steps of implantation of ionic species, bonding and fracture.

A method for paving a support with vignettes is already known in the prior art. This method consists in fastening a source substrate on a first rigid frame by means of a first ultra-violet-sensitive adhesive tape. The source substrate is then cut into vignettes according to the desired geometry using a diamond saw. After insolation of the first adhesive tape, the vignettes are repositioned on a second rigid frame provided with a second ultra-violet-sensitive adhesive tape according to the desired positioning. Then the surface of the vignettes is bonded by direct bonding on the surface of a handle substrate and the second tape is insolated to separate the vignettes from the second rigid frame. After a consolidation annealing of the direct bonding, the vignettes undergo technological steps such as, for example, steps of transferring thin film taken from the surface of the vignettes onto a receiver support according to a Smart Cut™ method.

However, this known paving method involves numerous drawbacks. On the one hand, the cutting of the vignettes by a diamond saw leads to a significant particulate and metallic contamination. On the other hand, the use of an adhesive tape leads to an organic pollution, which is difficult to clean before carrying out the first direct bonding. There are cleaning and surface preparation solutions that are effective, but they are aggressive and incompatible with the presence of the adhesive tape that maintains the vignettes. Finally, it is difficult to grind the different heights of the vignettes and then to polish their surface because the space between the vignettes leads to a greater erosion of the edges of the vignettes, which are more exposed to attack by the polishing device.

One of the aims of the present invention is to overcome at least one of these drawbacks. To this end, the present invention proposes a method for manufacturing a paved structure comprising:
a) providing a vignetted structure comprising a rigid frame, vignettes bonded in a spaced manner on the rigid frame provided with an UV-sensitive adhesive film, such as an acrylate polymer,
b) bonding the vignettes to a support substrate through a mineral-based paste so as to form a stack,
c) applying a pressure on the stack so that the mineral-based paste fills the space between the vignettes,
d) insolating the UV-sensitive adhesive film,
e) separating the rigid frame and the vignettes integral with the support substrate, and
f) applying a thermal treatment so as to transform the mineral-based paste into a cohesive mineral material to obtain the paved structure.

The method of the invention makes it possible to transfer the vignettes on a support substrate by bonding via a mineral-based paste. This bonding is less restrictive in terms of surface preparation than a direct bonding by molecular adhesion. The thermal treatment according to step f) allows the densification of the mineral-based paste, the elimination of the organic elements and the aggregation and/or the sintering of the grains of the mineral powder constituting the paste, as will be seen in detail thereafter, to lead to the obtaining of a cohesive mineral material. This cohesive mineral material has a mechanical resistance and a sufficient adhesion force to carry out a possible operation of grinding of the vignettes in order to form a flat surface as well as a possible implantation of ionic species in order to carry out a transfer by Smart Cut™.

The application of a pressure on the stack according to step c) is carried out so that the mineral-based paste fills the space between the vignettes until it comes into contact with the UV-sensitive adhesive film.

For example, the pressure applied to the stack according to step c) is about ten kN, and in particular the pressure is comprised between 5 and 10 kN.

Concretely, the thermal treatment of step f) is carried out in a stepwise manner.

According to one possibility, the thermal treatment of step f) is carried out at a temperature comprised between the ambient temperature and a temperature of approximately 450° C. depending on the material(s) constituting the vignettes and the mineral-based paste used to obtain a cohesive mineral material. For example, for a mineral-based paste of the ‘frit glass FX-11-036’ type of the company Ferro, the temperature is maintained at 125° C. for 30 min then at 300° C. for 60 min then at 425° C. for 90 min so as to obtain the desired cohesive mineral material.

According to one arrangement, the method comprises, after step f), a step g) of planarizing the upper surface of all the vignettes, so that the vignettes collectively form a flat surface. The presence of the cohesive mineral material facilitates the grinding and the polishing because the edge of the vignettes is less exposed than when they are bonded by direct bonding without filler material in the space between the vignettes. In addition, the obtaining of such a flat surface facilitates carrying out the collective technological steps, such as functionalization or transfers of thin film.

In practice, the planarization step g) is carried out by lapping then by chemical mechanical polishing, so as to reach a surface roughness of the vignettes compatible with a direct bonding, for example a surface roughness <0.5 nm RMS measured by AFM on a scan of 1*1 μm².

According to one possibility, the method comprises, after the planarization step g), a step h) of performing a selective chemical etching on the exposed face of the paved structure, so as to etch the cohesive mineral material faster than the exposed surface of the vignettes.

The chemical attack is carried out in particular by an aqueous solution of HF at 10% vol. for a duration allowing to obtain a removal of a few tens of nanometers of the cohesive mineral material with respect to the surface of the vignettes.

According to one possibility, the method comprises before step a):
a step i) of bonding in a detachable manner between a source substrate of vignettes and a handle substrate,
a step ii) of vignetting the source substrate bonded to the handle substrate, in particular carried out by photolithography and etching, so as to singularize the vignettes,
a step iii) of fastening the vignettes in a spaced manner on the rigid frame provided with the UV-sensitive adhesive film, and
a step iv) of removal the handle substrate from the vignettes, so as to obtain the vignetted structure provided in step a).

These steps of preparing the vignetted structure without using a diamond saw limit particulate and metallic contamination of the vignettes.

According to one possibility, the removable bonding according to step i) is obtained by using an adhesive layer and a removable layer at the bonding interface between the source substrate and the handle substrate. Indeed, the removable layer limits the energy of adhesion with the adhesive layer so as to allow the removal of step iv) at the interface between the removable layer and the adhesive layer by inserting a wedge at said interface.

Concretely, the removable layer is made of a material chosen from a chlorinated compound, such as octadecyltrichlorosilane, and a fluorinated polymer, such as Novec™ 2702 provided by 3M™, Novec™ 1720 of 3M™, the Optool fluorinated polymer developed by Daikin®, perfluorodecyltrichlorosilane, or perfluorodecyldimethylchlorosilane.

According to one characteristic, the adhesive layer is made of a material chosen from thermoplastic polymers, for example a BrewerBOND® 305 provided by the company Brewer Science.

Conveniently, the material of the removable layer is spread over the surface of the handle substrate. Since the subsequent cleaning of the removable layer is difficult, it is preferable to place it on the handle substrate and to place the adhesive layer on the source substrate.

The removal step iv) also comprises the removal of the adhesive layer by cleaning the vignetted structure using in particular D-limonene then isopropanol when the adhesive layer is made of BrewerBOND® 305. These components are inert vis-à-vis the vignetted structure.

According to one variant of the vignetted structure provided in step a), the removable bonding according to step i) is obtained by the use of an adhesive dry film, chosen from silicone-based polymers, in particular SPIS DFTA23 available in the professional range of Shin-Etsu®. This adhesive dry film is easy to use, it does not require spreading by centrifugation or annealing step. It makes it possible to reach a sufficient adhesion energy for carrying out vignetting of the source substrate without prohibiting the removal step iv) of removal the handle substrate by inserting a wedge at the interface.

Once the handle substrate has been detached, step iv) of the method further comprises removing by simple cleaning the adhesive dry film from the surface of the vignettes with a solution comprising p-menthol then a solution comprising isopropanol. This solution is inert vis-à-vis the vignetted structure.

According to one variant of the vignetted structure, the method uses a vignetting technology by laser treatment, which consists of cutting by laser damage, well known under the name ‘Stealth Dicing’ (SD) and for example described in the following articles: Masayoshi Kumagai et al, IEEE TRANSACTIONS ON SEMICONDUCTOR MANUFACTURING, VOL. 20, NO. 3, August 2007, Cereno, D I and Wickramanayaka, S, 2017 IEEE 67TH ELECTRONIC COMPONENTS AND TECHNOLOGY CONFERENCE (ECTC 2017), pp. 358-363, and Gaudiuso, C; Volpe, A and Ancona, A, March 2020, MICROMACHINES 11.

Also, according to this alternative, the method comprises before step a):
a step j) of laser treating a source substrate bonded on a bearing frame provided with an UV-sensitive adhesive tape so as to preform cut lines within the source substrate, the cut lines being intended to form the vignettes,
a step jj) of extending the adhesive tape so as to cause the source substrate to break along the preformed cut lines and to form the vignettes, and
a step jjj) of fastening the vignettes on the rigid frame provided with an UV-sensitive adhesive film, and
a step jjjj) of separating the bearing frame and the vignettes comprising the insolation of the UV-sensitive adhesive tape, so as to obtain the vignetted structure provided in step a).

This alternative avoids the use of photolithography and etching steps in the source substrate in order to provide the vignettes.

According to one possibility, the rigid frame and the UV-sensitive adhesive film respectively used in step iii) or in step jjj) have a diameter greater than that of the source substrate,
and the method comprises respectively in step iii) or jjj) the fastening of the vignettes by increasing the space between the vignettes, by modifying the initial position of the vignettes and/or by fastening vignettes of several source substrates on a single support substrate larger in diameter than the source substrate.

According to one possibility, the method further comprises after step f), and for example after step g) or h):
a step k) of implanting ionic species in the vignettes of the paved structure so as to create an embrittlement plane in each vignette delimiting a thin film between the implanted face and said embrittlement plane,
a step I) of performing a molecular bonding of the implanted face of the vignettes on a receiver substrate,
a step m) of fracture at the level of the embrittlement plane, in particular by applying a thermal treatment, so as to collectively transfer the thin film of each vignette onto the receiver substrate.

According to one arrangement, steps k, l and m) are repeated n times on the negative obtained at the end of step m), the negative comprising the support substrate and the vignettes, so as to carry out n new collective transfers of the thin film of each vignette on a receiver support.

According to another possibility, the method comprises, after step f), and for example after step g) or h), carrying out technological steps collectively on the vignettes of the paved structure.

Conveniently, the mineral-based paste comprises a mineral powder, a binder and a homogenization solvent.

Concretely, the mineral powder comprises grains having a size less than or equal to one tenth of the inter-chip space between the adjacent vignettes so as to facilitate the filling of the inter-chip space during step c). This size limitation makes it easier to fill the inter-chip spaces with the mineral-based paste. Then the densification/sintering obtained by the thermal treatment according to step f) makes it possible to solidarize and to enlarge these grains leading to the obtaining of the cohesive mineral material.

According to other characteristics, the method for manufacturing a paved structure includes one or more of the following optional characteristics considered alone or in combination:
The mineral-based paste is spread prior to the bonding of step b) on the exposed face of the vignettes and/or on the support substrate.
The insolation step d) is carried out before step c) of applying a pressure.
The insolation step d) is carried out after step c) of applying a pressure.
The removable layer and the adhesive layer formed according to step i), are annealed by applying a thermal treatment.
The source substrate is formed by at least one material constituting the vignettes of the paved structure and comprises at least one semiconductor material, in particular chosen from the column IV and the columns III/V of the periodic table of the elements.
The materials of the vignettes are chosen from the semiconductor materials, in particular chosen from the column IV and the columns III/V of the periodic table of the elements and for example silicon, Ge, InP, AsGa, SiC, glass, alumina, sapphire, LNO, LTO and quartz.
The vignettes of the paved structure are all made of the same and unique material.
The paved structure comprises vignettes of different materials.
Each of the vignettes of the paved structure is composed of a composite structure, the composite structure comprising different or identical materials.
The space between two adjacent vignettes of the vignetted structure is comprised between 100 and 200 micrometers.
Each vignette has a main face of polygonal shape, for example square or rectangular, or an oval or circular shape.
Step ii) comprises a step of removing the vignettes at the edge of the handle substrate, the main face of which has a shape different from that of the majority of the vignettes.
The mineral-based paste is only formed by a mineral powder, a binder and a homogenization solvent.
The mineral powder is chosen from metallic powders, metalloid powders, ceramic powders and a combination of these powders, in particular metalloid or ceramic powders so as to avoid a metallic contamination and for example a powder of a composition identical to that of the vignettes.
The metallic powders are chosen from silver, copper, tin and tungsten, for example.
The metalloid powders are chosen from silicon, germanium, and antimony, for example.
The ceramic powders are chosen from oxides and silicates, for example SiO₂, GeO₂, Al₂O₃, TiO₂, mica, etc.
The mineral-based paste is composed so as to have the necessary properties to be able to be spread by screen printing or by strip casting.
The amount of homogenization solvent is chosen so that said mineral-based paste has a viscosity comprised between 10 and 500 Pa·s.
The homogenization solvent is chosen in particular from N-methyl-2-pyrrolidone, terpinol, and limonene.
The nature of the binder of the mineral-based paste is chosen so as to impart a cohesion to the mineral-based paste.
The binder of the mineral-based paste is chosen from mineral materials, organic materials and a combination of these materials.
The mineral materials forming the binder of the mineral-based paste are chosen from doped glass of the alkaline polysilicate Li₂Si₅O₁₁ type, polyphosphate (NaPO₃)n, and phosphate H₂LiPO₄.
The organic materials forming the binder of the mineral-based paste are polymer materials, such as vinylidene polyfluoride, polyvinylpyrrolidone, ethyl cellulose, or polyethylene glycol.
The mineral-based paste is made of ‘glass frit FX-11-036’ compound available from the company Ferro.
The mineral-based paste is made up of a mixture of a silica mineral powder (Aerosil® R202—5 g), of an ethyl cellulose binder (Sigma Aldrich®—0.5 g) and of a homogenization solvent made of Terpinol (Sigma Aldrich®—5 g).
The n times repetition of steps k, l and m) on the negative obtained at the end of step m), comprises beforehand carrying out step g) of planarizing the upper surface of all the vignettes, and/or a step h) of performing a selective chemical attack on the exposed face of the paved structure, so as to remove the area damaged by the implantation of ionic species according to step k) previously carried out, and obtain the removal of the cohesive mineral material resulting from the mineral-based paste with respect to the surface of the vignettes.
The steps described above are repeated n times until the residual thickness of the vignettes is no longer sufficient to perform a collective transfer of the films.
The rigid frame is a frame made of metal, of the type of metallic DISCO® frame, or a rigid frame made up of any other material non-contaminating under the conditions of use.
The handle substrate is made of silicon.
The support substrate is made of silicon.
The UV-sensitive adhesive film and tape are made of acrylate polymer, in particular made of ‘SP-537T-230’ compound available from the company Furukawa Electric.

Other aspects, aims and advantages of the present invention will appear better on reading the following description of various variants thereof, given by way of non-limiting example and made with reference to the appended drawings. The figures do not necessarily respect the scale of all the elements represented so as to improve their readability. Dotted lines symbolize an embrittlement plane formed in a substrate. In the following description, for the sake of simplification, identical, similar or equivalent elements of the different embodiments have the same numerical references.

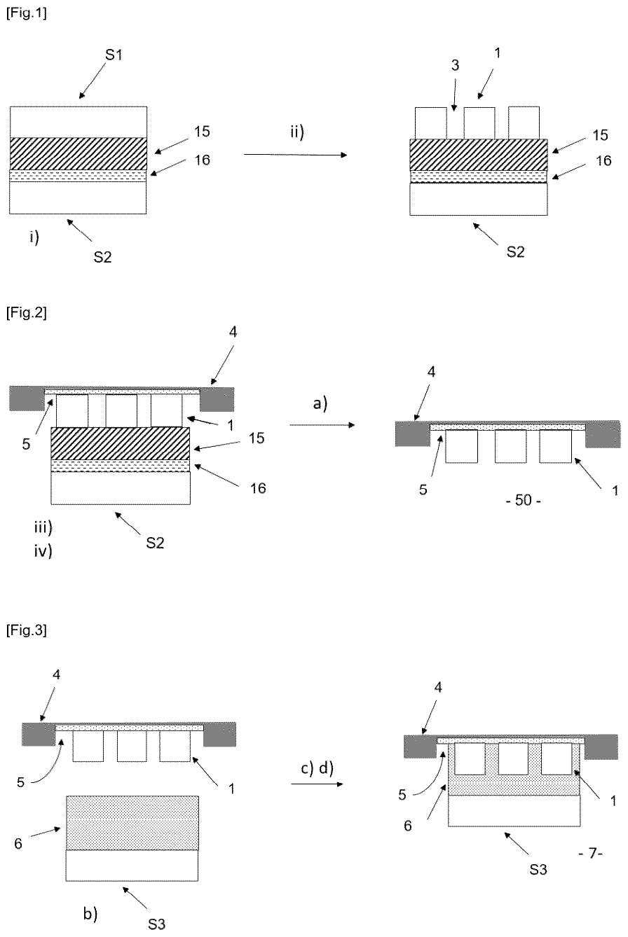

FIG. 1 is a schematic view illustrating steps i) and ii) of the method according to one embodiment of the invention.

FIG. 2 is a schematic view illustrating a step iii) of the method according to the embodiment of FIG. 1 and the provision of the vignetted structure a).

FIG. 3 is a schematic view illustrating steps b) to d) of the method according to the embodiment of FIG. 1.

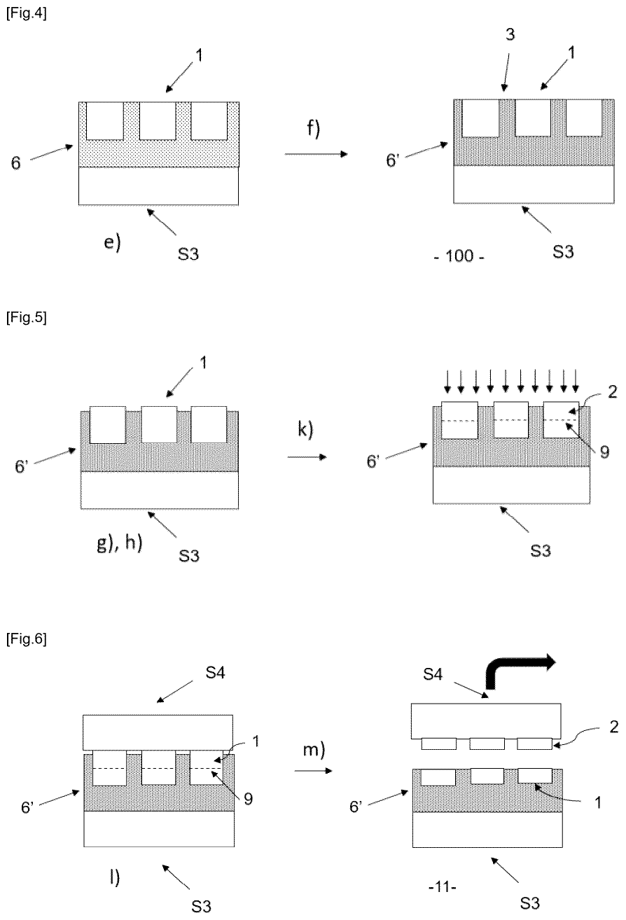

FIG. 4 is a schematic view illustrating steps e) and f) of the method of the embodiment of FIG. 1.

FIG. 5 is a schematic view illustrating steps g) and h) then step k) of implantation according to one embodiment of the invention.

FIG. 6 is a schematic view illustrating steps I) and m) of the method according to one embodiment of the invention.

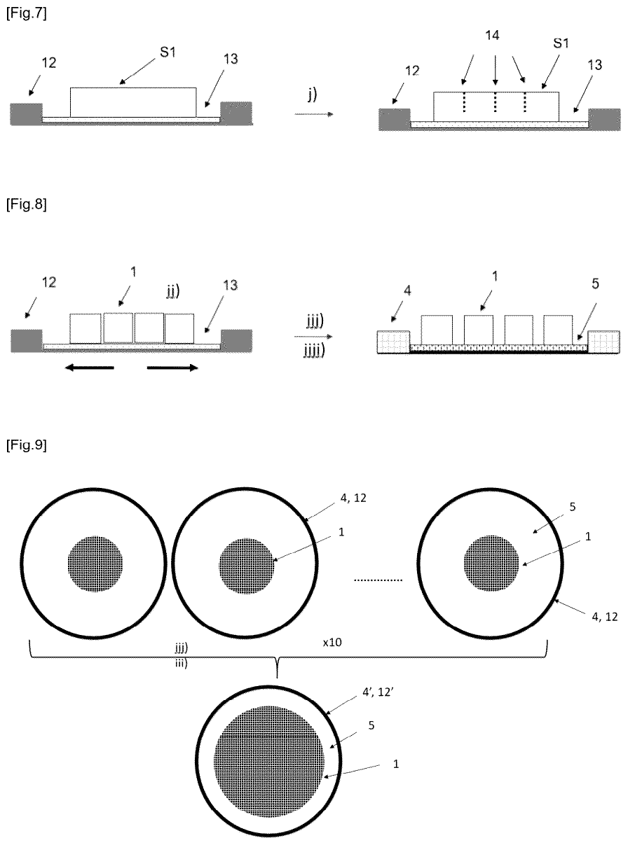

FIG. 7 is a schematic view illustrating a step j) of the method according to one possible embodiment of the invention.

FIG. 8 is a schematic view illustrating steps jj) to jjjj) of the method according to the embodiment of FIG. 7.

FIG. 9 is a schematic view illustrating a step jjj) or iii) of transferring vignettes of several source substrates onto a single frame of larger diameter according to one variant of the invention.

As illustrated in FIGS. 1 to 6, the method according to the invention comprises the preparation of a vignetted structure 50, the transfer of vignettes 1 onto a support substrate S3 so as to obtain a paved structure 100, steps of functionalizing the vignettes 1, and/or carrying out a collective transfer of a thin film 2 taken from each of the vignettes 1 onto a receiver substrate S4.

The method for manufacturing a paved structure 100 firstly comprises a step of detachable bonding a source substrate S1 on a handle substrate S2 (FIG. 1—step i) followed by a vignetting step comprising a photolithography of the surface of the source substrate S1 then an etching in the source substrate S1 forming trenches 3 to delimit spaced vignettes 1 (FIG. 1—step ii). A rigid frame 4 provided with an UV-sensitive adhesive film 5 is provided to fasten the vignettes 1 to it (FIG. 2—step iii). The handle substrate S2 is then detached at the level of the removable bonding interface so as to obtain the vignetted structure 50 which will be provided in step a) of the method (FIG. 2—step iv).

The vignettes 1 are then bonded on a support substrate S3 covered with a mineral-based paste 6 to form a stack 7 (FIG. 3). A pressure is applied on either side of the stack 7 so as to ensure the filling of the space 3 between the vignettes 1 by the mineral-based paste 6 (FIG. 3, steps b and c). A step d) of insolating the UV-sensitive adhesive film 5 is then carried out (FIG. 3) before separating the rigid frame 4 from the vignettes 1 integral with the support substrate S3, (FIG. 4—step e).

A thermal treatment is applied to:
allow the elimination of the organic components from the mineral-based paste 6,
densify the mineral paste 6 by aggregation and/or sintering of the mineral grains.

At the end of the thermal treatment, only the mineral part of the paste 6′ remains (FIG. 4, step f). The paved structure 100 is then obtained. This thermal treatment and this structuring of the cohesive mineral material 6′ also make it possible to increase the energy of adhesion of the vignettes 1 on the support substrate S3. A step g) of planarizing the upper surface 8 of all the vignettes 1 is then performed so that the vignettes 1 collectively form a flat surface (FIG. 5). Depending on the materials used and the performed planarization method, step g) is not sufficient to obtain a removal of the cohesive mineral material 6′ with respect to the surface of the vignettes 1 (or it is deliberately limited to reduce the costs), which risks hindering a future collective transfer by Smart Cut™ of the vignettes 1 onto a receiver substrate S4. A selective chemical etching step h) is then carried out so as to obtain a removal comprised between 10 and 20 nm of the cohesive mineral material 6′ derived from the mineral-based paste 6 in the space 3 between the vignettes 1 (FIG. 5).

The paved structure 100 thus prepared is advantageously used for a collective transfer of the thin film 2 originating from the vignettes 1 onto a receiver substrate S4. To do this, a step k) of implanting ionic species is carried out in the vignettes 1 so as to create an embrittlement plane 9 delimiting a thin film 2 in each vignette 1, the thin film 2 being comprised between the implanted surface and the embrittlement plane 9 (FIG. 5). The implanted paved structure 100 is then used for a molecular bonding on a receiver substrate S4 according to step I) of the method (FIG. 6). There follows a step m) of fracture at the level of the embrittlement plane 9 so as to collectively transfer the thin film 2 of each vignette 1 onto the receiver substrate S4 and obtain a new paved structure by direct bonding (FIG. 6). The negative 11 obtained at the end of the fracture of the paved structure 100 comprises the support substrate S3 and the thinned vignettes 1. This negative 11 is advantageously reused after planarization, polishing, etc., in a new collective transfer of the thin film 2 of the vignettes 1 onto a new receiver substrate S4 (FIG. 5).

One variant of the method according to the invention differs from that described above in that the vignetted structure 50 is prepared according to a ‘stealth dicing’ technology (FIG. 7). This variant comprises:
a step j) of laser treating a source substrate S1 bonded on a bearing frame 12 provided with an UV-sensitive adhesive tape 13, so as to preform cut lines 14 within the source substrate S1, the cut lines 14 being intended to form the vignettes 1 (FIG. 7),
a step jj) of extending the adhesive tape 13 so as to cause the source substrate S1 to break along the preformed cut lines 14 and form the vignettes 1, (FIG. 8),
a step jjj) of fastening the vignettes 1 on a rigid frame 4 provided with an UV-sensitive adhesive film 5, and a step jjjj) of separating the bearing frame 12 and the plurality of vignettes 1 comprising the insolation of the UV-sensitive adhesive tape 13 (FIG. 8) so as to obtain the vignetted structure 50 provided in step a).

According to yet another variant which differs from the method described above, the method comprises in step iii) or jjj) the provision respectively of a bearing frame 12 or of a rigid frame 4 provided with an UV-sensitive adhesive film 5 having a diameter greater than that of the source substrate S1, for example 300 nm and 100 nm respectively, so as to fasten vignettes 1 of several source substrates S1 on the same and unique rigid frame 4′ or bearing frame 12′ (FIG. 9). The fastening according to step iii) or jjj) is then advantageously carried out by a device for manipulating and transferring vignettes (Pick and Place) allowing the independent manipulation of each of the vignettes 1 or of a plurality of vignettes 1 at the same time. The following steps are carried out as previously described by using a support substrate S3 and a receiver substrate S4 with a diameter at least equal to the diameter of the disc defined by the vignettes 1 on the rigid frame 4′/bearing frame 12′ (not illustrated).

Detailed example embodiments of the method according to the invention follow below.

### EXAMPLE 1

A removable layer 16 of a fluoropolymer (Novec™ 2702) is formed by spreading on a handle substrate S2 made of silicon (200 mm in diameter and 725 μm in thickness), and the whole is annealed at 150° C. for 30 min. The thickness of the fluoropolymer film is about 10 nm.

An adhesive layer 15 is formed by spreading 40 μm of a adhesive resin BrewerBOND® 305 on a source substrate S1 made of silicon (200 mm in diameter and 725 μm in thickness) before performing a bonding with the handle substrate S2 at 210° C. so as to obtain a detachable bonding at the interface between the adhesive layer 15 and the fluoropolymer removable layer 16 (FIG. 1—step i).

The source substrate S1 is thinned by mechanical abrasion by means of a diamond wheel until it reaches a thickness of 500 μm. The surface is then wet cleaned. A photolithography of the source substrate S1 makes it possible to define vignettes 1 of 8×8 mm² with a space 3 of 100 μm between adjacent vignettes 1 (FIG. 1, step ii).

The vignettes 1 thus obtained have a thickness of 500 micrometers. They are then bonded on a metallic DISCO® rigid frame 4 by means of an UV-sensitive ‘SP-537T-230’ adhesive film 5 available from the company Furukawa (FIG. 2, step iii). The handle substrate S2 is then detached by inserting a wedge at the interface between the adhesive layer 15 and the removable layer 16 (step iv). The adhesive layer 15 is removed by cleaning with D-limonene and then isopropanol. The vignetted structure 50 comprising vignettes 1 bonded by an adhesive film 5 on a rigid frame 4 is thus obtained (FIG. 2) and may be provided according to step a) of the method of the invention.

On a silicon support substrate S3 (200 mm in diameter and 725 μm in thickness), approximately 100 μm of mineral-based paste 6 “glass frit FX-11-036” from the company Ferro is spread by screen printing. The UV-sensitive adhesive film of the vignetted structure 50 is insolated by UV irradiation (step d) then the support substrate S3 is brought into contact with the vignettes 1 so as to form a stack 7 (step b) while applying a pressure of 5 kN (FIG. 3, step c). Alternatively, it is possible to insolate the UV-sensitive adhesive film 5 (step d) after contacting.

The rigid frame 4 is separated from the stack 7 consisting of the support substrate S3 and of the vignettes 1 (FIG. 4, step e). An annealing by applying a thermal treatment at 125° C. for 30 min, then 300° C. for 60 min and 425° C. for 90 min (FIG. 4, step f) allows the transformation of the mineral-based paste 6 into cohesive mineral material 6′ and the obtaining of the paved structure 100. The vignettes 1 are integral with the support substrate S3 and the space 3 between the vignettes 1 is filled. The surface of the vignettes 1 is planarized by a mechanical lapping step then an in-depth chemical mechanical polishing step (step g). The polishing speed of the cohesive mineral material 6′ resulting from glass frit is greater than the polishing speed of silicon, which leads to a removal of the cohesive mineral material 6′ of approximately 20 nm with respect to the surface of the vignettes 1 made of silicon (FIG. 5).

The paved structure 100 thus prepared is subjected to a hydrogen ion implantation with an energy of 150 keV and a dose of 5.10¹⁶ ions/cm² (FIG. 5, step k). A receiver substrate S4 made of silicon (200 mm in diameter and 725 μm in thickness) is oxidized so as to form a 500 nm SiO₂ film at its surface (not represented). The receiver substrate S4 is then prepared so as to carry out a direct bonding with the implanted face of the vignettes 1 (FIG. 6, step l). An annealing at 500° C. makes it possible to obtain a fracture at the level of the embrittlement plane 9 and a thin film 2 with a thickness of 1.2 μm originating from each of the vignettes 1 is transferred onto the receiver substrate S4 (FIG. 6, step m). A chemical mechanical polishing of the negative 11 obtained at the end of step m) comprising the support substrate S3 and the vignettes 1 allows a new use in a method for transferring the thin film 2 as previously described according to steps k to m).

### EXAMPLE 2

A removable layer 16 of 10 nm of fluoropolymer (Novec™ 1720) is formed by spreading on a handle substrate S2 made of silicon (200 mm in diameter and 725 μm in thickness), and the whole is annealed at 135° C. for 15 min.

An adhesive layer 15 is formed by spreading 40 μm of an adhesive resin BrewerBOND® 305 on a source substrate S1 made of silicon (200 mm in diameter and 725 μm in thickness) before performing a bonding with the handle substrate S2 at 210° C. so as to obtain a detachable bonding at the interface between the adhesive layer 15 and the fluoropolymer layer 16 (FIG. 1, step i).

A photolithography in the silicon of the source substrate S1 makes it possible to define vignettes 1 of 20×20 mm² with a space 3 of 200 μm between the adjacent vignettes 1 (step ii).

The vignettes 1 thus obtained are bonded to a metallic DISCO® frame by means of an adhesive film 5 ‘SP-537T-230’ available from the company Furukawa (step iii). The handle substrate S2 is then detached by inserting a wedge at the interface between the adhesive layer 15 and the removable layer (FIG. 2, step iv). The adhesive layer 15 is then removed by cleaning with D-limonene and then isopropanol so as to obtain the vignetted structure 50.

On a silicon support substrate S3 (200 mm in diameter and 725 μm in thickness) approximately 100 μm of mineral-based paste 6 “glass frit FX-11-036” of the company Ferro is spread by screen printing (FIG. 3). The UV-sensitive adhesive film 5 of the vignetted structure 50 is insolated by UV irradiation (step d) then the vignettes 1 at the edge of the rigid frame 4 which do not have the desired shape (for example square) are removed by means of a suitable tool for manipulating and transferring vignettes (Pick and Place).

The support substrate S3 is then brought into contact with the vignettes 1 so as to form a stack 7 (FIG. 3 step b) while applying a pressure of 5 kN (step c).

The rigid frame 4 is separated from the stack 7 consisting of the support substrate S3 and the vignettes 1 (FIG. 4, step e). An annealing by applying a thermal treatment at 125° C. for 30 min, then 300° C. for 60 min and 425° C. for 90 min (step f) allows the transformation of the mineral-based paste into cohesive mineral material 6′ and the obtaining of the paved structure 100. The vignettes 1 are integral with the support substrate S3 and the space 3 between the vignettes 1 is filled. The surface of the vignettes 1 is planarized by a mechanical lapping step then a chemical mechanical polishing step (FIG. 5, step g) is applied lightly to avoid a significant wear of the consumables. However, the light polishing does not allow asufficient removal of the cohesive mineral material 6′ to be achieved, so a selective chemical attack completes it with an aqueous solution of HF at 10% vol. for 1 min (step h) and makes it possible to achieve a sufficient removal of the cohesive mineral material 6′ resulting from “glass frit”, for example 10 nm with respect to the surface of the silicon. The paved structure 100 thus prepared may be used as a donor substrate of the thin film 2 of Si in a Smart Cut™ transfer method (implantation, bonding, fracture).

### EXAMPLE 3

The Stealth Dicing technology is used to cut ten source substrates S1 of InP of 100 mm in diameter into chips of 10×10 mm². To do this, the source substrates S1 are each disposed on an UV-sensitive adhesive tape 13 disposed on a bearing frame 12. A laser treatment step is performed in each of the source substrates so as to preform cut lines 14 within the source substrate (step j-FIG. 7). The adhesive tape 13 is then stretched so as to cause the source substrate to break along the preformed cut lines 14 and form the vignettes 1 (FIG. 8, step jj).

A rigid frame 4′ of a size suitable for plates with a diameter of 300 mm and provided with an UV-sensitive adhesive film 5 is used to transfer the vignettes 1 of the ten source substrates S1 (FIG. 9) by means of a suitable tool for manipulating and transferring vignettes (Pick and Place). The non-square vignettes 1 at the edge of the frame have been removed beforehand (not illustrated).

On a silicon support substrate S3 (300 mm in diameter and 725 μm in thickness), approximately 100 μm of mineral-based paste 6 “glass frit FX-11-036” of the company Ferro is spread by screen printing. The support substrate S3 is brought into contact with the vignettes 1 so as to form a stack 7 (as in FIG. 3, step b) while applying a pressure of 10 kN (step c).

The UV-sensitive adhesive film 5 is insolated by UV and the rigid frame 4 is separated from the stack 7 consisting of the support substrate S3 and of the vignettes 1 (FIG. 4, step e). An annealing by applying a thermal treatment at 125° C. for 30 min, then 300° C. for 60 min and 350° C. for 300 min (step f) allows the transformation of the mineral-based paste 6 into cohesive mineral material 6′ and the obtaining of the paved structure 100. The vignettes 1 are integral with the support substrate S3 and the space 3 between the vignettes 1 is filled. The surface of the vignettes 1 is planarized by a mechanical lapping step then a light chemical mechanical polishing step (step g).

In order to increase the removal obtained by the chemical mechanical polishing of step g), it is completed by a selective chemical attack with an aqueous solution of HF at 10% vol. for 1 min (FIG. 5—step h). This allows a removal of cohesive mineral material 6′ resulting from “frit glass” of approximately 10 nm with respect to the surface of the InP.

The paved structure 100 thus prepared is subjected to a hydrogen ion implantation with an energy comprised between 60 and 100 keV and a dose comprised between 6 and 7.10¹⁶ ions/cm² depending on the thickness of the InP film to be transferred (FIG. 6, step k). A receiver substrate S4 made of silicon (300 mm in diameter and 725 μm in thickness) is oxidized so as to form a 200 nm SiO₂ film on its surface. The receiver substrate S4 is then prepared so as to achieve a direct bonding with the implanted face of the vignettes 1 (FIG. 6, step I). An annealing at 280° C. makes it possible to obtain a fracture at the level of the embrittlement plane 9 and a thin film 2 coming from each of the vignettes 1 is transferred onto the receiver substrate S4 (step m). A chemical mechanical polishing of the negative 11 obtained at the end of step m) comprising the support substrate S3 and the vignettes 1 allows a new use in a method for transferring the thin film 2 as previously described according to steps k to m).

### EXAMPLE 4

An adhesive dry film made of SPIS DFTA23 (Shin Etsu®) is deposited by spreading on a handle substrate S2 made of silicon of 200 mm in diameter (725 μm in thickness),

A detachable bonding of the handle substrate S2 with a source substrate S1 of 200 mm in diameter made of germanium is carried out at 90° C. (FIG. 1, step i). A photolithography of the source substrate S1 made of germanium makes it possible to define vignettes 1 of 2×12 mm² with a space 3 between the adjacent vignettes 1 of 200 μm (step ii).

The vignettes 1 thus obtained are bonded to a metallic DISCO® rigid frame 4 by means of an adhesive film 5 ‘SP-537T-230’ available from the company Furukawa (FIG. 2, step iii). The handle substrate S2 is then detached by inserting a wedge at the interface of the detachable bonding (FIG. 2, step iv).

The adhesive dry film made of SPIS DFTA23 is then removed by cleaning with p-menthol and then isopropanol. The vignetted structure 50 comprising vignettes 1 bonded by an adhesive film 5 made of SP-537T-230 on a rigid frame 4 is thus obtained. Said UV-sensitive adhesive film 5 is insolated by UV irradiation (FIG. 3, step d).

A mineral-based paste 6 based on silica is prepared by mixing 5 g of silica (Aerosil® R 202) 0.5 g of ethyl cellulose (Sigma-Aldrich®) and 5 g of terpinol (Sigma-Aldrich®). Approximately 100 μm of this mineral-based paste 6 is spread by screen printing on a silicon support substrate S3 (200 mm in diameter and 725 μm in thickness) before being brought into contact with the vignettes 1 so as to form a stack 7 (FIG. 3, step b) while applying a pressure of 5 kN (step c).

The rigid frame 4 is separated from the stack 7 consisting of the support substrate S3 and of the vignettes 1 (FIG. 4, step e). An annealing by applying a thermal treatment at 100° C. for 60 min, then 425° C. for 120 min (step f) allows the transformation of the mineral-based paste 6 into cohesive mineral material 6′ and the obtaining of the paved structure 100. The vignettes 1 are integral with the support substrate S3 and the space 3 between the vignettes 1 is filled. The surface of the vignettes 1 is planarized by a mechanical lapping step then a chemical mechanical polishing step (step g).

After this step g) a selective chemical attack with an aqueous solution of HF at 10% vol. for 1 min makes it possible to remove the cohesive mineral material 6′ by approximately 10 nm with respect to the surface of the silicon (FIG. 5, step h). The paved structure 100 thus prepared may be used as a donor substrate of the thin film 2 of Ge in a collective transfer method by the Smart Cut™ technology (implantation, bonding and fracture).

### EXAMPLE 5

Silicon plates of 200 mm in diameter and of 725 μm in thickness are used.

A removable layer 16 of fluoropolymer (Optool Daikin®) is formed by spreading on a handle substrate S2 made of silicon (200 mm in diameter and 725 μm in thickness) (FIG. 1).

An adhesive layer 15 is formed by spreading 40 μm of an adhesive resin BrewerBOND® 305 on a source substrate S1 made of silicon (200 mm in diameter and 725 μm in thickness) before performing a bonding with the handle substrate S2 at 210° C. so as to obtain a detachable bonding at the interface between the adhesive layer 15 and the fluoropolymer layer 16 (FIG. 1, step i).

A photolithography in the silicon of the source substrate S1 makes it possible to define vignettes 1 of 8×8 mm² with a space 3 of 100 μm between the adjacent vignettes 1 (step ii).

The vignettes 1 thus obtained are bonded on a metallic DISCO® frame by means of an adhesive film 5 ‘SP-537T-230’ available from the company Furukawa (FIG. 2, step iii). The handle substrate S2 is then detached by inserting a wedge at the interface between the adhesive layer 15 and the removable layer (step iv). The adhesive layer 15 is removed by cleaning with D-limonene and then isopropanol. The vignetted structure 50 comprising vignettes 1 bonded by an adhesive film 5 on a rigid frame 4 is thus obtained.

On a silicon support substrate S3 (200 mm in diameter and 725 μm in thickness), approximately 100 μm of mineral-based paste 6 “glass frit FX-11-036” of the company Ferro is spread by screen printing. The UV-sensitive adhesive film 5 of the vignetted structure 50 is insolated by UV irradiation (FIG. 3, step d) then the support substrate S3 is brought into contact with the vignettes 1 so as to form a stack 7 (step b) while applying a pressure of 5 kN (step c).

The rigid frame 4 is separated from the stack 7 consisting of the support substrate S3 and of the vignettes 1 due to the prior insolation of the film 5 (FIG. 4, step e). An annealing by applying a thermal treatment at 125° C. for 30 min, then 300° C. for 60 min and 425° C. for 90 min (step f) allows the transformation of the mineral-based paste 6 into cohesive mineral material 6′ and the obtaining of the paved structure 100. The vignettes 1 are integral with the support substrate S3 and the space 3 between the vignettes 1 is filled. The surface of the vignettes 1 is planarized by a mechanical lapping step then a chemical mechanical polishing step (FIG. 5, step g). The polishing speed of the cohesive mineral material 6′ resulting from glass frit is greater than the polishing speed of silicon, which leads to a removal of the cohesive mineral material 6′ of approximately 20 nm with respect to the surface of the vignettes 1 made of silicon (no completion of step h) in this example).

The paved structure 100 thus prepared may be used as a donor substrate of the thin film 2 of Si in a Smart Cut™ transfer method (implantation, bonding, fracture) as described above.

Thus the present invention proposes a method for manufacturing a paved structure 100 comprising vignettes made of semiconductor material and configured to be used as a donor substrate and to collectively transfer the thin film of each vignette onto a receiver substrate by Smart Cut™, while limiting the number of surface cleaning steps and the cycle time.

1. A method for manufacturing a paved structure comprising:
a) providing a vignetted structure comprising a rigid frame, vignettes bonded in a spaced manner on the rigid frame provided with an UV-sensitive adhesive film,
b) bonding the vignettes to a support substrate through a mineral-based paste so as to form a stack,
c) applying a pressure on the stack so that the mineral-based paste fills the space between the vignettes,
d) insolating the UV-sensitive adhesive film,
e) separating the rigid frame and the vignettes integral with the support substrate, and
f) applying a thermal treatment so as to transform the mineral-based paste into a cohesive mineral material to obtain the paved structure.

2. The method for manufacturing a paved structure according to claim 1, comprising, after step f), a step g) of planarizing the upper surface of all the vignettes, so that the vignettes collectively form a flat surface.

3. The method for manufacturing a paved structure according to claim 2, comprising, after planarization step g), a step h) of performing a selective chemical etching on the exposed face of the paved structure, so as to etch the cohesive mineral material faster than the exposed surface of the vignettes.

4. The method for manufacturing a paved structure according to claim 1, comprising, before step a):
a step i) of bonding in a detachable manner between a source substrate of vignettes and a handle substrate,
a step ii) of vignetting the source substrate bonded to the handle substrate, so as to singularize the vignettes,
a step iii) of fastening the vignettes in a spaced manner on the rigid frame provided with the UV-sensitive adhesive film, and
a step iv) of removal the handle substrate from the vignettes, so as to obtain the vignetted structure provided in step a).

5. The method for manufacturing a paved structure according to claim 1, comprising, before step a):
a step j) of laser treating a source substrate bonded on a bearing frame provided with an UV-sensitive adhesive tape so as to preform cut lines within the source substrate, the cut lines being intended to form the vignettes,
a step jj) of extending the adhesive tape so as to cause the source substrate to break along the preformed cut lines and form the vignettes, and
a step jjj) of fastening the vignettes on the rigid frame provided with an UV-sensitive adhesive film, and
a step jjjj) of separating the bearing frame and the vignettes comprising the insolation of the UV-sensitive adhesive tape, so as to obtain the vignetted structure provided in step a).

6. The method for manufacturing a paved structure according to claim 4, wherein the rigid frame and the UV-sensitive adhesive film respectively used in step iii) or in step jjj) have a diameter greater than that of the source substrate,
and wherein step iii) or step jjj) comprises fastening vignettes by increasing the space between the vignettes, by modifying the initial position of the vignettes and/or by fastening vignettes of several source substrates on a single rigid frame of a diameter greater than that of the source substrate.

7. The method for manufacturing a paved structure according to claim 1, further comprising, after step f):
a step k) of implanting ionic species in the vignettes of the paved structure so as to create an embrittlement plane in each vignette delimiting a thin film between the implanted face and said embrittlement plane,
a step l) of performing a molecular bonding of the implanted face of the vignettes on a receiver substrate,
a step m) of fracture at the level of the embrittlement plane, so as to collectively transfer the thin film of each vignette onto the receiver substrate and obtain a negative comprising the support substrate and the vignettes.

8. The method for manufacturing a paved structure according to claim 7, wherein steps k, 1 and m) are repeated n times on the negative obtained at the end of step m), the negative comprising the support substrate and the vignettes, so as to carry out n new collective transfers of the thin film of each vignette onto a receiver support.

9. The method for manufacturing a paved structure according to claim 1, wherein the mineral-based paste comprises a mineral powder, a binder and a homogenization solvent.

10. The method for manufacturing a paved structure according to claim 9, wherein the mineral powder comprises grains having a size less than or equal to one tenth of the inter-chip space between the adjacent vignettes so as to facilitate the filling of the inter-chip space during step c).
